(19) United States
(12) Patent Application Publication
(10) Pub. No.: US 2023/0136198 A1
(43) Pub. Date: May 4, 2023

(54) WIEN FILTER AND MULTIPLE ELECTRON BEAM INSPECTION APPARATUS

(71) Applicant: NuFlare Technology, Inc., Yokohama-shi (JP)

(72) Inventor: Toshikatsu AKIBA, Yokohama-shi (JP)

(73) Assignee: NuFlare Technology, Inc., Yokohama-shi (JP)

(21) Appl. No.: 18/147,263

(22) Filed: Dec. 28, 2022

Related U.S. Application Data
(63) Continuation of application No. PCT/JP2021/023343, filed on Jun. 21, 2021.

(30) Foreign Application Priority Data
Oct. 28, 2020 (JP) 2020-180675

(51) Int. Cl. H01J 37/05; G01N 23/2251

(52) U.S. Cl. CPC H01J 37/05; G01N 23/2251; G01N 2223/30; G01N 2223/07; G01N 2223/507; H01J 2237/2448; H01J 2237/057; H01J 37/26

(57) ABSTRACT

A Wien filter includes a cylindrical yoke, a plurality of magnetic poles arranged at intervals along an inner periphery of the yoke, the magnetic poles each joined at one end thereof to the yoke, a coil wound on each of the plurality of magnetic poles, and an electrode disposed at the other end of each of the plurality of magnetic poles, with an insulator between the electrode and the magnetic pole. The magnetic poles each has a recess at the other end thereof, and the insulator and the electrode may be disposed in the recess.

### TECHNICAL FIELD

The present invention relates to a Wien filter and a multiple electron beam inspection apparatus.

### BACKGROUND ART

As LSI circuits are increasing in density, the line width of circuits of semiconductor devices is becoming finer. To form a desired circuit pattern onto a semiconductor device, a method of reducing and transferring, by using a reduction-projection exposure apparatus, onto a wafer a highly precise original image pattern formed on a quartz is employed.

An improvement in yield is indispensable for the fabrication of LSI, which takes a massive fabrication cost. With miniaturization of the dimensions of the LSI pattern formed on a semiconductor wafer, the dimensions of pattern defects to be detected are also extremely small. Thus, high precision of a pattern inspection apparatus that inspects a hyperfine pattern transferred onto a semiconductor wafer for defects is needed.

As an inspection method for pattern defects, there is known a method of comparing a measurement image obtained by capturing a pattern formed on a substrate, such as a semiconductor wafer and a lithography mask, with design data or a measurement image obtained by capturing the same pattern on the substrate. Examples of the inspection method include “die-to-die inspection” that compares pieces of measurement image data obtained by capturing the same patterns at different locations on the same substrate and “die-to-database inspection” that generates design image data (reference image) based on pattern-designed design data and that compares the design image data with a measurement image that is measurement data obtained by capturing a pattern. When the compared images do not match, it is determined that there are pattern defects.

There has been developing an inspection apparatus that acquires a pattern image by scanning on a substrate to be inspected with electron beams and detecting secondary electrons emitted from the substrate with application of electron beams. Development of an apparatus using multiple beams as an inspection apparatus using electron beams has been proceeding.

When a substrate to be inspected is irradiated with multiple beams (multiple primary electron beams), a flux of secondary electrons (multiple secondary electron beams) including reflected electrons corresponding to respective ones of the multiple beams is emitted from the substrate to be inspected. The multiple beam inspection apparatus includes a Wien filter for separating multiple secondary electron beams from multiple primary electron beams.

In a plane orthogonal to a beam traveling direction (or path central axis), the Wien filter generates an electric field and a magnetic field in directions orthogonal to each other. The multiple primary electron beams that enter the Wien filter from above travel straight downward, because forces of the electric and magnetic fields acting on the multiple primary electron beams cancel each other out. On the other hand, the multiple secondary electron beams that enter the Wien filter from below are bent obliquely upward and separated from the multiple primary electron beams, because forces of the electric and magnetic fields act in the same direction on the multiple secondary electron beams.

In a conventional Wien filter, a plurality of electromagnetic poles are arranged at regular intervals on the same inner circumference of a cylindrical yoke, and the electromagnetic poles each have a coil wound thereon. A voltage applied to each electromagnetic pole and the amount of current passing through the coil are controlled, so that the electric and magnetic fields are superimposed.

The cylindrical yoke has a ground potential. Each electromagnetic pole is joined to the inner periphery of the cylindrical yoke, with an insulator therebetween. The insulator has a resistance (magnetic resistance) against a magnetic flux generated in the coil. To provide an efficient Wien filter that uses less coil current, the insulator is required to be reduced in thickness. With a thin insulator, however, there is an increased risk of discharge between the cylindrical yoke and the electromagnetic pole (high-voltage portion) to which a voltage is applied.
Patent Literature 1: JP 11-233062 A
Patent Literature 2: JP 2007-27136 A
Patent Literature 3: JP 2018-10714 A
Patent Literature 4: JP 2006-277996 A

### SUMMARY OF INVENTION

An object of the present invention is to provide a Wien filter that has a low risk of discharge and operates efficiently and stably, and to also provide a multiple electron beam inspection apparatus that includes the Wien filter.

According to one aspect of the present invention, a Wien filter includes a cylindrical yoke, a plurality of magnetic poles arranged at intervals along an inner periphery of the yoke, the magnetic poles each joined at one end thereof to the yoke, a coil wound on each of the plurality of magnetic poles, and an electrode disposed at the other end of each of the plurality of magnetic poles, with an insulator between the electrode and the magnetic pole.

According to one aspect of the present invention, a multiple electron beam inspection apparatus includes an optical system irradiating a substrate with multiple primary electron beams, a beam separator separating, from the multiple primary electron beams, multiple secondary electron beams emitted as a result of irradiating the substrate with the multiple primary electron beams, and a detector detecting the multiple secondary electron beams separated. The above Wien filter is used as the beam separator.

### Advantageous Effects of Invention

The present invention can reduce the risk of discharge in the Wien filter and allow the Wien filter to operate efficiently and stably.

### BRIEF DESCRIPTION OF DRAWINGS

FIG. 1 is a schematic cross-sectional diagram of a Wien filter according to an embodiment of the present invention.

FIG. 2 is a perspective view of a magnetic pole.

FIG. 3 is a perspective view of a magnetic pole according to another embodiment.

FIG. 4 is a schematic diagram of the magnetic pole and an electrode according to the embodiment.

FIG. 5 is a schematic diagram of a magnetic pole and an electrode according to another embodiment.

FIG. 6A is a schematic diagram of a Wien filter according to another embodiment, and FIG. 6B is an enlarged view of part of the Wien filter.

FIG. 7A and FIG. 7B are schematic diagrams each illustrating a magnetic pole according to another embodiment.

FIG. 8 is a schematic diagram of a Wien filter according to another embodiment.

FIG. 9 is a diagram illustrating a general configuration of a pattern inspection apparatus according to an embodiment.

FIG. 10 is a plan view of a shaping aperture array substrate.

FIG. 11 is a schematic diagram illustrating electromagnetic poles of a Wien filter according to a comparative example.

### DESCRIPTION OF EMBODIMENTS

Hereinafter, embodiments of the present invention will be described on the basis of the drawings.

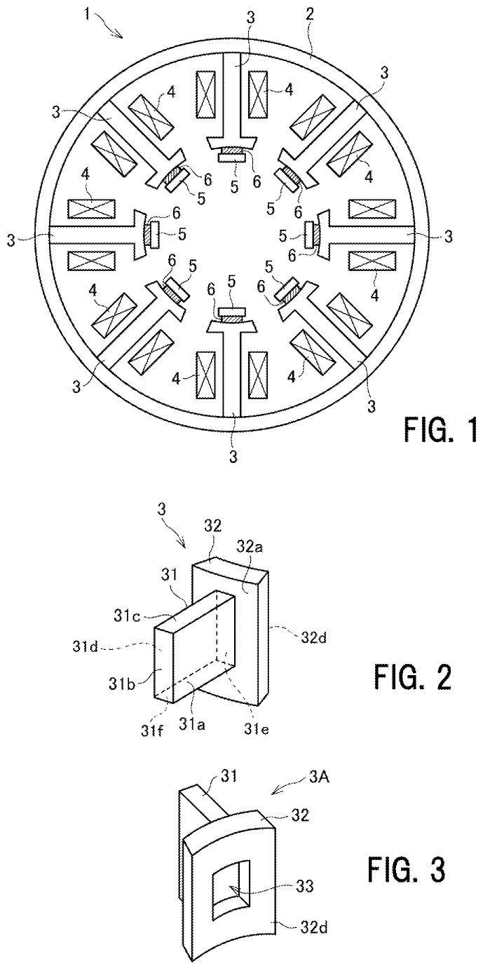

FIG. 1 is a schematic cross-sectional diagram of a Wien filter 1 according to an embodiment of the present invention. The Wien filter 1 includes a cylindrical yoke 2 and a plurality of magnetic poles 3 arranged along the inner periphery of the yoke 2. The plurality of magnetic poles 3 are arranged at regular intervals on the same circumference about the cylindrical axis of the yoke 2. Eight magnetic poles 3 are arranged in the example illustrated in FIG. 1.

Each magnetic pole 3 of the Wien filter 1 has a coil 4 wound thereon. The magnetic pole 3 extends in the radial direction of the yoke 2. The magnetic pole 3 is joined to the yoke 2 at one end thereof, and has an electrode 5 at the other end thereof (or at an end portion thereof adjacent to the yoke center), with an insulator 6 between the magnetic pole 3 and the electrode 5. A space in the yoke center surrounded by a plurality of electrodes 5 is a beam passage region.

Each coil 4 is connected to a current source (not shown) and configured to allow the amount of current to be independently controlled. Each electrode 5 is connected to a voltage source (not shown) outside the yoke and configured to allow a voltage applied thereto to be independently controlled. The yoke 2 has a ground potential.

The yoke 2 and the magnetic pole 3 may be made of a magnetic material, such as permalloy. The electrode 5 may be a conductive member, such as a copper plate. The insulator 6 may be made of, for example, a ceramic material.

As illustrated in FIG. 2, the magnetic pole 3 includes a first plate portion 31 and a second plate portion 32 coupled to the first plate portion 31.

The first plate portion 31 has six surfaces: a first principal plate surface 31a, a second principal plate surface 31d opposite the first principal plate surface 31a, a proximal end 31b, a distal end 31e opposite the proximal end 31b, an upper surface 31c, and a lower surface 31f opposite the upper surface 31c. The first principal plate surface 31a and the second principal plate surface 31d are substantially parallel to the radial direction of the yoke 2.

The first plate portion 31 is joined at the proximal end 31b thereof to the inner periphery of the yoke 2. The distal end 31e of the first plate portion 31 is smaller than a first principal plate surface 32a of the second plate portion 32. The distal end 31e is joined to a center of the first principal plate surface 32a. The first plate portion 31 is joined to the second plate portion 32 in such a way as to be substantially perpendicular to the first principal plate surface 32a. The first plate portion 31 and the second plate portion 32 may be formed as an integral unit having the structure described above.

A second principal plate surface 32d opposite the first principal plate surface 32a of the second plate portion 32 is slightly curved toward the first principal plate surface 32a.

The coil 4 described above is wound around the first principal plate surface 31a, the upper surface 31c, the second principal plate surface 31d, and the lower surface 31f of the first plate portion 31. The electrode 5 is disposed on the second principal plate surface 32d of the second plate portion 32, with the insulator 6 therebetween.

An electric field is generated by controlling a voltage applied to each electrode 5. A magnetic field orthogonal to the electric field is generated by controlling current in each coil 4. For example, an electric field is generated by applying predetermined voltages (e.g., +5 kV for one electrode 5 and −5 kV for the other electrode) from the voltage source to the electrodes 5 at the 6 o'clock and 12 o'clock positions in FIG. 1. Also, when a magnetic flux is generated by controlling the amount of current passing through the coils 4 at the 3 o'clock and 9 o'clock positions using the current source, the magnetic flux flows from the magnetic pole 3 at the 3 o'clock position through the yoke 2 to the magnetic pole 3 at the 9 o'clock position to generate a magnetic field orthogonal to the electric field.

Referring to FIG. 11, a conventional Wien filter applies a voltage to a magnetic pole 70 (electromagnetic pole) having the coil 4 thereon to generate an electric field. For example, an electric field is generated by applying a voltage of +5 kV and a voltage of −5 kV to one and the other of the magnetic poles 70 at the 6 o'clock and 12 o'clock positions. Also, when a magnetic flux is generated by controlling the amount of current passing through the coils 4 at the 3 o'clock and 9 o'clock positions, the magnetic flux flows from the magnetic pole 70 at the 3 o'clock position through the yoke 2 to the magnetic pole 70 at the 9 o'clock position to generate a magnetic field orthogonal to the electric field. Since the yoke 2 has a ground potential, the magnetic pole 70 and the yoke 2 need to be provided with an insulator 72 therebetween. When the insulator 72 is thick (i.e., there is a large insulation gap), the resulting large magnetic resistance makes passage of the magnetic flux difficult and increases the amount of coil current required. When the insulator 72 is made thinner to reduce the increase in coil current, there is an increased risk of discharge between the yoke 2 and the magnetic pole 70 to which a predetermined voltage for generating an electric field is applied.

In the present embodiment, on the other hand, a voltage for generating an electric field is applied to the electrode 5 separate from the magnetic pole 3 constituting a magnetic circuit. Since the insulator 6 interposed between the magnetic pole 3 and the electrode 5 has little impact on the magnetic resistance, it is possible to leave a sufficient insulation gap and reduce the risk of discharge. Also, since the yoke 2 and the magnetic pole 3 do not require an insulator therebetween, there is no need to increase coil current and the Wien filter can operate efficiently and stably.

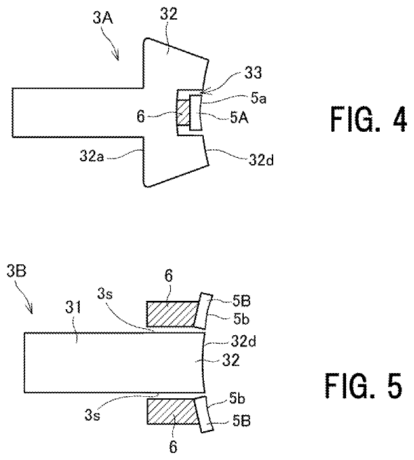

As illustrated in FIG. 3 and FIG. 4, a magnetic pole 3A may have, in the center of the second principal plate surface 32d of the second plate portion 32, a recess 33 toward the first principal plate surface 32a. The magnetic pole 3A may have an electrode 5A at the bottom (or on the innermost surface) of the recess 33, with the insulator 6 between the magnetic pole 3A and the electrode 5A. It is preferable that the electrode 5A and the insulator 6 be accommodated in the recess 33, and that a surface 5a of the electrode 5A and the second principal plate surface 32d of the second plate portion 32 be curved surfaces with the same radius of curvature. Referring to FIG. 4, which is a cross-sectional plan view, the magnetic pole 3A may be regarded as having a magnetic pole structure divided into two parts, with the recess 33 therebetween.

As illustrated in FIG. 5, a plate-like magnetic pole 3B may include the second plate portion 32 having a width equal to the plate thickness of the first plate portion 31, and an electrode 5B and the insulator 6 may be disposed on each of both sides of the second plate portion 32. The insulator 6 is formed into a plate shape and secured in place, with the electrode 5B attached to the insulator 6 in such a way that the electrode 5B can be disposed at a distance of about 2 mm from a side 3s of the magnetic pole 3B. The insulator 6 may be secured to the side 3s of the magnetic pole 3B, or may be secured to a component separate from the Wien filter 1 so that the insulator 6 is separated from the magnetic pole 3B. It is preferable that surfaces 5b of the electrodes 5B and the second principal plate surface 32d of the second plate portion 32 (i.e., an end face of the magnetic pole 3B adjacent to the beam passage region) be curved surfaces with the same radius of curvature. In this structure, two separate electrodes 5B are arranged, with the magnetic pole 3B therebetween.

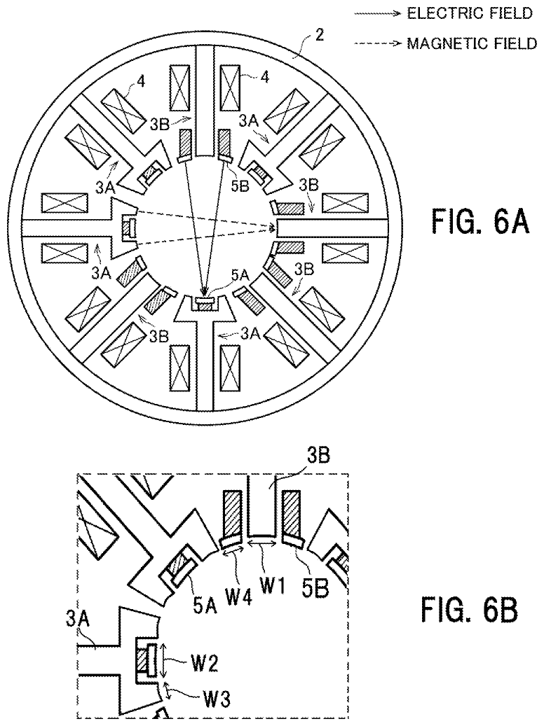

As illustrated in FIG. 6A, the Wien filter may include both the magnetic poles 3A and 3B. The magnetic poles 3A and 3B are arranged opposite each other, with the center of the yoke 2 therebetween. When orthogonal electric and magnetic fields are generated as illustrated, an electrode structure that generates the electric field is the same as a magnetic pole structure that generates the magnetic field. That is, the electrodes 5B (two separate electrodes) on the respective sides of the magnetic pole 3B and the electrode 5A (single electrode) in the recess 33 of the magnetic pole 3A generate an electric field. Also, the magnetic pole 3A having a structure divided into two parts, with the recess 33 therebetween, and the plate-like single magnetic pole 3B generate a magnetic field. With this configuration, when a plurality of electrons (multiple beams) pass through the beam passage region, the electric and magnetic fields on the axis of deflection control of the plurality of electrons are uniform and this enables deflection with high accuracy.

For example, by applying a voltage to the electrodes 5B (two separate electrodes) at the 12 o'clock position in FIG. 6A, an electric field is generated toward the electrode 5A (single electrode) at the 6 o'clock position opposite the 12 o'clock position. Also, by exciting the coil 4, a magnetic field emerges from the magnetic pole surface of the magnetic pole 3A (with a magnetic pole structure divided into two parts) at the 9 o'clock position, toward the magnetic pole surface of the magnetic pole 3B at the 3 o'clock position opposite the 9 o'clock position. The electric and magnetic fields thus generated are orthogonal to each other and enable the function of the Wien filter. This relation produces similar effects on opposite electrodes and magnetic poles. The electric and magnetic fields on the axis of deflection control can thus be made uniform.

In the Wien filter that includes both the magnetic poles 3A and 3B, as illustrated in FIG. 6B, a width W1 of the magnetic pole 3B in a yoke circumferential direction (i.e., a circumferential direction of a circle concentric with the inner periphery of the yoke) may be equal to a width W2 of the electrode 5A in the circumferential direction, and a width W3 of a magnetic pole surface of the magnetic pole 3A divided into two parts (i.e., a portion adjacent to the recess 33 in the yoke circumferential direction) may be equal to a width W4 of the electrode 5B in the circumferential direction. This improves symmetry of the structure and enables deflection control with higher accuracy.

The first plate portion 31 and the second plate portion 32 of any of the magnetic poles 3, 3A, and 3B may be formed as an integral unit or may be separate components coupled together. Also, the yoke 2 and any of the magnetic poles 3, 3A, and 3B may be formed as an integral unit or may be separate components coupled together.

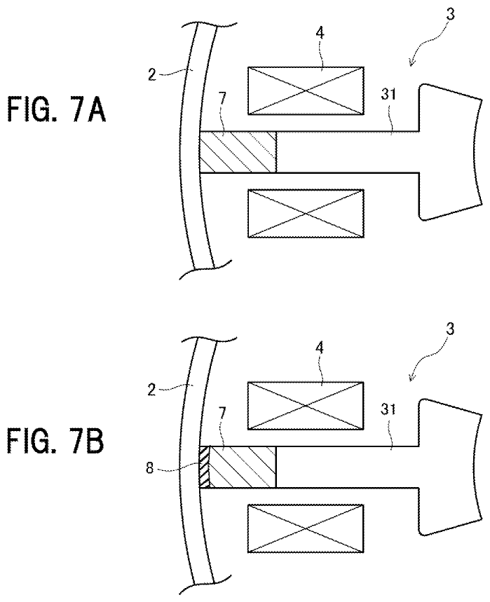

In the embodiments described above, the electrode 5 is provided separately from the magnetic pole 3, and a voltage for generating an electric field is not applied to the magnetic pole 3. As illustrated in FIG. 7A, however, a high-resistance permanent magnet 7 may be provided between the yoke 2 and the first plate portion 31 of the magnetic pole 3 (electromagnetic pole) and a voltage may be applied to the magnetic pole 3. A high-resistance material, such as ferrite, may be used to form the permanent magnet 7.

With the configuration illustrated in FIG. 7A, the permanent magnet 7 can reduce the occurrence of discharge between the magnetic pole 3 and the yoke 2. Using both the permanent magnet 7 and an electromagnet (the magnetic pole 3 and the coil 4) can facilitate controlling a magnetic field.

With the configuration Illustrated in FIG. 7A, the high-resistance permanent magnet 7 disposed between the first plate portion 31 and the yoke 2 allows a voltage drop between a high-voltage portion (magnetic pole 3) and a ground portion (yoke 2) and this can reduce the risk of discharge. Also, since an electrode structure that generates an electric field and a magnetic pole structure that generates a magnetic field can be formed as a common structure, orthogonal electric and magnetic fields are similarly distributed and it is possible to simplify the structure and improve accuracy of beam control.

When the permanent magnet 7 is a permanent magnet member, such as a rubber magnet, that can be roughly regarded as an insulator, the high-voltage portion can be insulated from the ground portion and this can reduce the risk of discharge. Also, since the permanent magnet 7 provides a magnetomotive force for generating a magnetic field, it is possible to reduce magnetic-field control current flowing through the coil 4 and reduce the risk of heat generation.

Since the permanent magnet 7 allows a voltage drop and reduces the risk of discharge, the permanent magnet 7 and the yoke 2 may be provided with an insulator 8 therebetween, as illustrated in FIG. 7B, so as to ensure isolation from the ground portion (yoke 2). The insulator 8 may be made of the same material as the insulator 6.

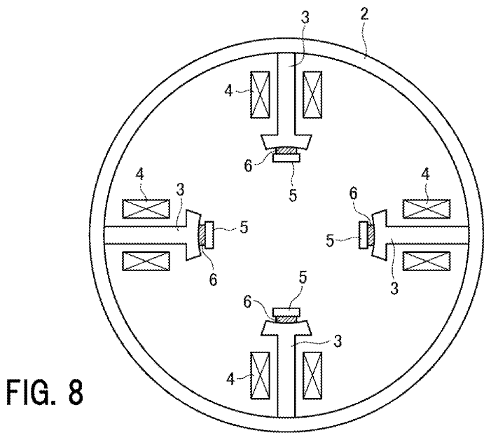

Although the Wien filter includes eight magnetic poles 3 in the embodiments described above, the number of magnetic poles 3 is not limited, as long as orthogonal electric and magnetic fields can be generated. For example, the Wien filter may include four magnetic poles 3 as illustrated in FIG. 8, or may include sixteen magnetic poles 3 (not shown).

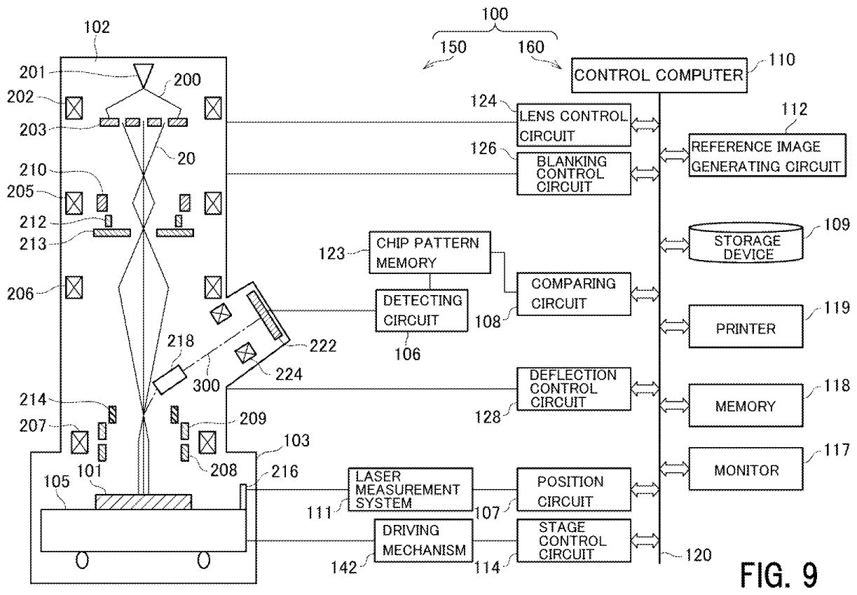

Next, a pattern inspection apparatus 100 including the Wien filter will be described with reference to FIG. 9. The pattern inspection apparatus 100 is configured to obtain a secondary electron image by irradiating a substrate to be inspected, with multiple beams composed of electron beams.

As illustrated in FIG. 9, the pattern inspection apparatus 100 includes an image acquiring mechanism 150 and a control system circuit 160. The image acquiring mechanism 150 includes an electron beam column 102 (electron beam optics) and an inspection chamber 103. The electron beam column 102 includes therein an electron gun 201, an electromagnetic lens 202, a shaping aperture array substrate 203, an electromagnetic lens 205, an electrostatic lens 210, a collective blanking deflector 212, a limiting aperture substrate 213, an electromagnetic lens 206, an electromagnetic lens 207 (objective lens), a main deflector 208, a sub-deflector 209, a beam separator 214, a deflector 218, an electromagnetic lens 224, and a multi-detector 222.

A stage 105 movable in the horizontal direction, the rotational direction and the height direction is disposed in the inspection chamber 103. A substrate 101 (sample) to be inspected is placed on the stage 105. Examples of the substrate 101 include an exposure mask substrate and a semiconductor substrate, such as a silicon wafer. When the substrate 101 is a semiconductor substrate, a plurality of chip patterns (wafer dies) are formed on the semiconductor substrate. When the substrate 101 is an exposure mask substrate, a chip pattern is formed on the exposure mask substrate. The chip pattern is composed of a plurality of figure patterns. The chip pattern formed on the exposure mask substrate is exposed and transferred onto a semiconductor substrate multiple times, so that a plurality of chip patterns (wafer dies) are formed on the semiconductor substrate.

The substrate 101 is placed on the stage 105, with a pattern side thereof facing upward. The stage 105 has a mirror 216 disposed thereon. The mirror 216 reflects laser light for laser measurement emitted from a laser measurement system 111 disposed outside the inspection chamber 103.

The multi-detector 222 is connected to a detecting circuit 106 outside the electron beam column 102. The detecting circuit 106 is connected to a chip pattern memory 123.

In the control system circuit 160, a control computer 110 that controls the overall operation of the inspection apparatus 100 is connected through a bus 120 to a position circuit 107, a comparing circuit 108, a reference image generating circuit 112, a stage control circuit 114, a lens control circuit 124, a blanking control circuit 126, a deflection control circuit 128, a storage device 109 such as a magnetic disk device, a monitor 117, a memory 118, and a printer 119.

The deflection control circuit 128 is connected through a digital-to-analog converter (DAC) amplifier (not shown) to the main deflector 208, the sub-deflector 209, and the deflector 218.

The chip pattern memory 123 is connected to the comparing circuit 108.

The stage 105 is driven by a driving mechanism 142 under the control of the stage control circuit 114. The stage 105 is movable in the horizontal direction and the rotational direction. The stage 105 is also movable in the height direction.

The laser measurement system 111 measures the position of the stage 105 by receiving light reflected off the mirror 216 using the principle of laser interferometry. The position of the stage 105 measured by the laser measurement system 111 is sent to the position circuit 107.

The lens control circuit 124 controls the electromagnetic lens 202, the electromagnetic lens 205, the electromagnetic lens 206, the electromagnetic lens 207 (objective lens), the electrostatic lens 210, the electromagnetic lens 224, and the beam separator 214.

The electrostatic lens 210 is composed of, for example, three or more electrode substrates that are open in the center thereof. An electrode substrate in the middle of the electrostatic lens 210 is controlled by the lens control circuit 124 through a DAC amplifier (not shown), and upper and lower electrode substrates of the electrostatic lens 210 are supplied with a ground potential.

The collective blanking deflector 212 is composed of two or more electrodes, each of which is controlled by the blanking control circuit 126 through a DAC amplifier (not shown).

The sub-deflector 209 is composed of four or more electrodes, each of which is controlled by the deflection control circuit 128 through a DAC amplifier. The main deflector 208 is composed of four or more electrodes, each of which is controlled by the deflection control circuit 128 through a DAC amplifier. The deflector 218 is composed of four or more electrodes, each of which is controlled by the deflection control circuit 128 through a DAC amplifier.

A high-voltage power supply circuit (not shown) is connected to the electron gun 201. By applying an acceleration voltage from the high-voltage power supply circuit between a filament (cathode) and an extraction electrode (anode) (not shown) in the electron gun 201, applying a voltage to another extraction electrode (Wehnelt), and heating the cathode to a predetermined temperature, a group of electrons emitted from the cathode is accelerated and emitted as an electron beam 200.

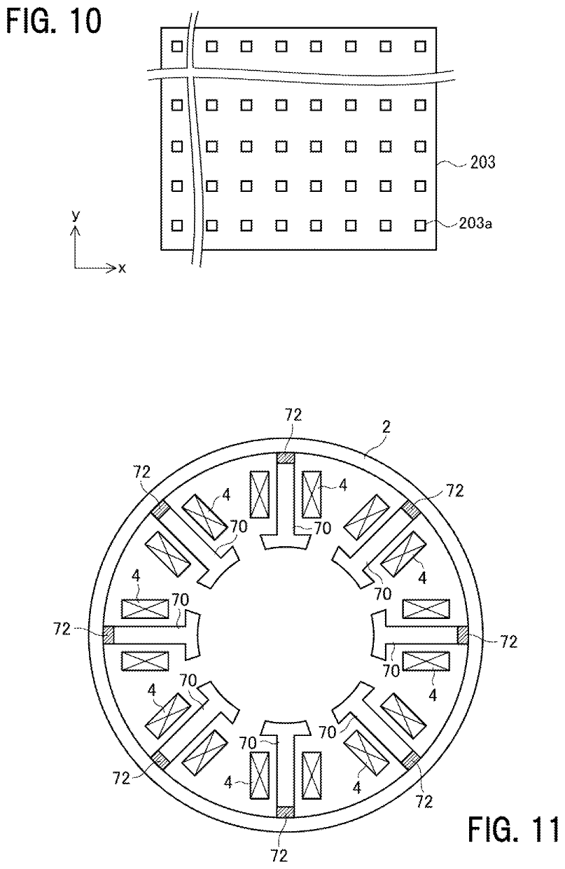

FIG. 10 is a conceptual diagram illustrating a configuration of the shaping aperture array substrate 203. The shaping aperture array substrate 203 has a two-dimensional array of apertures 203a arranged at a predetermined pitch in the x and y directions. The apertures 203a are rectangular or circular apertures with the same shape and size. Part of the electron beam 200 passes through the plurality of apertures 203a to form multiple beams MB.

An operation of the image acquiring mechanism 150 of the inspection apparatus 100 will now be described.

The electron beam 200 emitted from the electron gun 201 (emission source) is refracted by the electromagnetic lens 202 and illuminates the entire shaping aperture array substrate 203. The shaping aperture array substrate 203 has the plurality of apertures 203a as illustrated in FIG. 10. A region of the shaping aperture array substrate 203 including the plurality of apertures 203a is illuminated with the electron beam 200. The electron beam 200 with which the apertures 203a are irradiated passes through the apertures 203a to form multiple beams MB (multiple primary electron beams).

The multiple beams MB are refracted by the electromagnetic lens 205 and the electromagnetic lens 206 to repeatedly form an image and a crossover, and pass through the beam separator 214 disposed at a crossover of the multiple beams MB to reach the electromagnetic lens 207 (objective lens). The electromagnetic lens 207 focuses the multiple beams MB onto the substrate 101. The multiple beams MB brought into focus on the surface of the substrate 101 (sample) by the electromagnetic lens 207 are deflected together by the main deflector 208 and the sub-deflector 209 to the respective irradiation positions on the substrate 101.

When all the multiple beams MB are deflected together by the collective blanking deflector 212, the multiple beams MB are displaced from a center hole of the limiting aperture substrate 213 and blocked by the limiting aperture substrate 213. On the other hand, the multiple beams MB not deflected by the collective blanking deflector 212 pass through the center hole of the limiting aperture substrate 213, as illustrated in FIG. 9. Turning on and off the collective blanking deflector 212 enables blanking control that collectively controls the on and off of the beams.

When the substrate 101 is irradiated with the multiple beams MB at desired positions, a flux of secondary electrons (multiple secondary electron beams 300) including reflected electrons corresponding to respective ones of the multiple beams MB (multiple primary electron beams) is emitted from the substrate 101.

The multiple secondary electron beams 300 emitted from the substrate 101 pass through the electromagnetic lens 207 to reach the beam separator 214.

The Wien filter according to any of the embodiments described above is used as the beam separator 214. In a plane orthogonal to the direction in which a central beam of the multiple beams MB travels (i.e., in a plane orthogonal to the central axis of the path), the beam separator 214 generates an electric field and a magnetic field in directions orthogonal to each other. The electric field exerts force in the same direction regardless of the direction of travel of electrons. On the other hand, the magnetic field exerts force in accordance with the Fleming's left-hand rule. The direction of force acting on electrons can thus be changed by the direction of travel of the electrons.

The multiple beams MB that enter the beam separator 214 from above travel straight downward, because the forces exerted by the electric and magnetic fields and acting on the multiple beams MB cancel each other out. On the other hand, the multiple secondary electron beams 300 that enter the beam separator 214 from below are bent obliquely upward and separated from the multiple beams MB, because the forces exerted by the electric and magnetic fields act in the same direction on the multiple secondary electron beams 300.

The multiple secondary electron beams 300 bent obliquely upward and separated from the multiple beams MB are deflected by the deflector 218, refracted by the electromagnetic lens 224, and projected onto the multi-detector 222. Note that FIG. 9 gives a simplified view, which does not depict the refraction of the path of the multiple secondary electron beams 300.

The multi-detector 222 detects the multiple secondary electron beams 300 projected thereon. The multi-detector 222 includes, for example, a diode-type two-dimensional sensor (not shown). The secondary electrons of the multiple secondary electron beams 300 collide with the diode-type two-dimensional sensor at positions corresponding to respective beams of the multiple beams MB. This multiplies the electrons inside the sensor, and generates secondary electron image data for each pixel from an amplified signal.

Detection data of secondary electrons detected by the multi-detector 222 (i.e., measured image, secondary electron image, or image to be inspected) is output to the detecting circuit 106 in order of measurement. In the detecting circuit 106, analog detection data is converted to digital data by an analog-to-digital (A/D) converter (not shown) and stored in the chip pattern memory 123. The image acquiring mechanism 150 thus acquires a measured image of a pattern formed on the substrate 101.

The reference image generating circuit 112 generates a reference image for each mask die, on the basis of design data serving as a basis for forming a pattern on the substrate 101, or design pattern data defined by exposure image data of a pattern formed on the substrate 101. For example, design pattern data is read from the storage device 109 through the control computer 110, and each figure pattern defined by the read design pattern data is converted to binary or multilevel image data.

Figures defined by the design pattern data are composed of basic elements, such as a rectangle and a triangle. Figure data is stored, which defines the shape, size, position, and others of each pattern figure by using information, such as coordinates (x, y) of a reference position of the figure, lengths of sides of the figure, and a figure code serving as an identifier for identifying the figure type, such as rectangle or triangle.

When design pattern data used as figure data is received by the reference image generating circuit 112, the data is developed into data of each figure, and the figure code indicating the figure shape of the figure data and the figure dimensions are interpreted. Then, the figure data is developed into binary or multilevel image data of the design pattern as a pattern to be arranged within squares in units of grids of predetermined quantization dimensions, and output.

In other words, the design data is read, the occupancy of a figure in the design pattern is calculated for each of squares into which an inspection region is virtually divided in units of predetermined dimensions, and n-bit occupancy data is output. For example, it is preferable to set one square as one pixel. When one pixel is given a resolution of 1/2⁸ (=1/256), small regions with a resolution of 1/256 are allocated to the region of a figure in the pixel to calculate the occupancy in the pixel. The calculated occupancy is output as 8-bit occupancy data to the reference image generating circuit 112. The square (inspection pixel) is simply sized to match the pixel of measured data.

The reference image generating circuit 112 then performs appropriate filter processing on design image data of the design pattern which is image data of the figure. Optical image data (measured image) is under the action of filtering performed thereon by the optical system or, in other words, in an analog state that continuously changes. Therefore, by also performing filter processing on image data of the design pattern which is design-side image data whose image intensity (gray value) is a digital value, it is possible to adjust the image data to the measured data. The generated image data of a reference image is output to the comparing circuit 108.

The comparing circuit 108 compares the measured image (image to be inspected) obtained by measuring the substrate 101 with the reference image corresponding thereto. Specifically, the image to be inspected and the reference image, which are positioned with respect to each other, are compared pixel-by-pixel. The comparing circuit 108 compares them pixel-by-pixel by using a predetermined determination threshold, in accordance with predetermined determination conditions, and determines whether there is a defect, such as a shape defect. For example, if a difference in pixel-by-pixel gray level is greater than a determination threshold Th, the comparing circuit 108 determines the pixel as a defect candidate, and outputs the result of the comparison. The result of the comparison may be stored in the storage device 109 or the memory 118, displayed on the monitor 117, or may be printed out from the printer 119.

Besides the die-to-database inspection described above, the die-to-die inspection may be performed. The die-to-die inspection compares data of measured images obtained by imaging the same patterns at different points on the same substrate 101. Accordingly, from the substrate 101 on which the same figure patterns (first and second figure patterns) are formed at different positions by the multiple beams MB (electron beams), the image acquiring mechanism 150 acquires measured images that are secondary electron images of one figure pattern (first figure pattern) and the other figure pattern (second figure pattern). In this case, the acquired measured image of the one figure pattern serves as a reference image, and the acquired measured image of the other figure pattern serves as an image to be inspected. The acquired images of the one figure pattern (first figure pattern) and the other figure pattern (second figure pattern) may be within the same chip pattern data, or may be separate in different pieces of chip pattern data. The inspection may be carried out in the same manner as the die-to-database inspection.

The Wien filter 1 according to any of the embodiments described above is used as the beam separator 214. This can reduce the risk of discharge in the image acquiring mechanism 150 and enables efficient and stable operation.

Although the present invention has been described in detail using specific embodiments, it will be apparent to those skilled in the art that various modifications can be made without departing from the intent and scope of the present invention.

This application is based on Japanese Patent Application 2020-180675 filed on Oct. 28, 2020, which is incorporated by reference in its entirety.

### REFERENCE SIGNS LIST

1: Wien filter
2: yoke
3, 3A, 3B: magnetic pole
4: coil
5, 5A, 5B: electrode
6, 8: insulator
100: pattern inspection apparatus

1-22. (canceled)

23. A Wien filter comprising:
a cylindrical yoke;
a plurality of magnetic poles arranged at intervals along an inner periphery of the yoke, the magnetic poles each joined at one end thereof to the yoke;
a coil wound on each of the plurality of magnetic poles; and
an electrode disposed at the other end of each of the plurality of magnetic poles, with an insulator between the electrode and the magnetic pole, wherein
the magnetic poles each have a recess at the other end thereof, and
the insulator and the electrode are disposed in the recess.

24. A Wien filter comprising:
a cylindrical yoke;
a plurality of magnetic poles arranged at intervals along an inner periphery of the yoke, the magnetic poles each joined at one end thereof to the yoke;
a coil wound on each of the plurality of magnetic poles; and
an electrode disposed at the other end of each of the plurality of magnetic poles, with an insulator between the electrode and the magnetic pole, wherein
the plurality of magnetic poles each include
a first plate portion joined at a proximal end thereof to the inner periphery of the yoke, and
a second plate portion disposed at a distal end of the first plate portion, the distal end being opposite to the proximal end,
the coil is wound on the first plate portion,
the first plate portion is coupled to a first principal plate surface of the second plate portion, and a second principal plate surface opposite to the first principal plate surface is curved toward the first principal plate surface,
the second principal plate surface has a recess, and
the insulator and the electrode are disposed in the recess.

25. The Wien filter according to claim 24, wherein a surface of the electrode and the second principal plate surface are curved surfaces with the same radius of curvature.

26. A Wien filter comprising:
a cylindrical yoke;
a plurality of magnetic poles arranged at intervals along an inner periphery of the yoke, the magnetic poles each joined at one end thereof to the yoke;
a coil wound on each of the plurality of magnetic poles; and
an electrode disposed at the other end of each of the plurality of magnetic poles, with an insulator between the electrode and the magnetic pole,
wherein the insulator and the electrode are disposed on each of both sides of the magnetic pole.

27. A Wien filter comprising:
a cylindrical yoke;
a plurality of magnetic poles arranged at intervals along an inner periphery of the yoke, the magnetic poles each joined at one end thereof to the yoke;
a coil wound on each of the plurality of magnetic poles; and
an electrode disposed at the other end of each of the plurality of magnetic poles, with an insulator between the electrode and the magnetic pole,
wherein the plurality of magnetic poles includes a first magnetic pole with a single electrode disposed at an end portion thereof adjacent to a center of the yoke, and a second magnetic pole with an electrode disposed on each of both sides thereof.

28. The Wien filter according to claim 27, wherein the first magnetic pole and the second magnetic pole are arranged opposite to each other, with the center of the yoke therebetween.

29. The Wien filter according to claim 28, wherein
the first magnetic pole has a recess at the end portion thereof, and the insulator and a first electrode are disposed in the recess,
a width of the second magnetic pole in a circumferential direction of the yoke is equal to a width of the first electrode in the circumferential direction of the yoke, and
a width of a portion of a magnetic pole surface of the first magnetic pole, the portion being adjacent to the recess in the circumferential direction of the yoke, is equal to a width of a second electrode in the circumferential direction of the yoke, the second electrode being disposed on one of the sides of the second magnetic pole.

30. A multiple electron beam inspection apparatus comprising:
an optical system irradiating a substrate with multiple primary electron beams;
a beam separator separating, from the multiple primary electron beams, multiple secondary electron beams emitted as a result of irradiating the substrate with the multiple primary electron beams; and
a detector detecting the multiple secondary electron beams separated, wherein
the beam separator is a Wien filter including
a cylindrical yoke,
a plurality of magnetic poles arranged at intervals along an inner periphery of the yoke, the magnetic poles each joined at one end thereof to the yoke,
a coil wound on each of the plurality of magnetic poles, and
an electrode disposed at the other end of each of the plurality of magnetic poles, with an insulator between the electrode and the magnetic pole,
a space in a center of the yoke is a beam passage region,
the magnetic poles each have a recess at the other end thereof, and
the insulator and the electrode are disposed in the recess.

31. A multiple electron beam inspection apparatus comprising:
an optical system irradiating a substrate with multiple primary electron beams;
a beam separator separating, from the multiple primary electron beams, multiple secondary electron beams emitted as a result of irradiating the substrate with the multiple primary electron beams; and
a detector detecting the multiple secondary electron beams separated, wherein
the beam separator is a Wien filter including
a cylindrical yoke,
a plurality of magnetic poles arranged at intervals along an inner periphery of the yoke, the magnetic poles each joined at one end thereof to the yoke,
a coil wound on each of the plurality of magnetic poles, and
an electrode disposed at the other end of each of the plurality of magnetic poles, with an insulator between the electrode and the magnetic pole,
a space in a center of the yoke is a beam passage region,
the plurality of magnetic poles each include
a first plate portion joined at a proximal end thereof to the inner periphery of the yoke, and
a second plate portion disposed at a distal end of the first plate portion, the distal end being opposite to the proximal end,
the coil is wound on the first plate portion,
the first plate portion is coupled to a first principal plate surface of the second plate portion, and a second principal plate surface opposite to the first principal plate surface is curved toward the first principal plate surface,
the second principal plate surface has a recess, and
the insulator and the electrode are disposed in the recess.

32. The multiple electron beam inspection apparatus according to claim 31, wherein a surface of the electrode and the second principal plate surface are curved surfaces with the same radius of curvature.

33. A multiple electron beam inspection apparatus comprising:
an optical system irradiating a substrate with multiple primary electron beams;
a beam separator separating, from the multiple primary electron beams, multiple secondary electron beams emitted as a result of irradiating the substrate with the multiple primary electron beams; and
a detector detecting the multiple secondary electron beams separated, wherein
the beam separator is a Wien filter including
a cylindrical yoke,
a plurality of magnetic poles arranged at intervals along an inner periphery of the yoke, the magnetic poles each joined at one end thereof to the yoke, and
a coil wound on each of the plurality of magnetic poles,
an electrode disposed at the other end of each of the plurality of magnetic poles, with an insulator between the electrode and the magnetic pole,
a space in a center of the yoke is a beam passage region, and
the insulator and the electrode are disposed on each of both sides of the magnetic pole.

34. Multiple electron beam inspection apparatus comprising:
an optical system irradiating a substrate with multiple primary electron beams;
a beam separator separating, from the multiple primary electron beams, multiple secondary electron beams emitted as a result of irradiating the substrate with the multiple primary electron beams; and
a detector detecting the multiple secondary electron beams separated, wherein
the beam separator is a Wien filter including
a cylindrical yoke,
a plurality of magnetic poles arranged at intervals along an inner periphery of the yoke, the magnetic poles each joined at one end thereof to the yoke, and
a coil wound on each of the plurality of magnetic poles,
an electrode disposed at the other end of each of the plurality of magnetic poles, with an insulator between the electrode and the magnetic pole,
a space in a center of the yoke is a beam passage region, and
the plurality of magnetic poles include a first magnetic pole with a single electrode disposed at an end portion thereof adjacent to a center of the yoke, and a second magnetic pole with an electrode disposed on each of both sides thereof.

35. The multiple electron beam inspection apparatus according to claim 34, wherein the first magnetic pole and the second magnetic pole are arranged opposite to each other, with the center of the yoke therebetween.

36. The multiple electron beam inspection apparatus according to claim 35, wherein
the first magnetic pole has a recess at the end portion thereof, and the insulator and a first electrode are disposed in the recess,
a width of the second magnetic pole in a circumferential direction of the yoke is equal to a width of the first electrode in the circumferential direction of the yoke, and
a width of a portion of a magnetic pole surface of the first magnetic pole, the portion being adjacent to the recess in the circumferential direction of the yoke, is equal to a width of a second electrode in the circumferential direction of the yoke, the second electrode being disposed on one of the sides of the second magnetic pole.
